(19) United States
(12) Patent Application Publication
(10) Pub. No.: US 2017/0141319 A1
(43) Pub. Date: May 18, 2017

(54) CARBON NANOTUBE INTERLAYER, MANUFACTURING METHOD THEREOF, AND THIN FILM TRANSISTOR USING THE SAME

(71) Applicant: DONGGUK UNIVERSITY INDUSTRAY-ACADEMIC COOPERATION FOUNDATION, Seoul (KR)

(72) Inventor: Yong Young NOH, Daejeon (KR)

(73) Assignee: DONGGUK UNIVERSITY INDUSTRAY-ACADEMIC COOPERATION FOUNDATION, Seoul (KR)

(21) Appl. No.: 15/309,800

(22) PCT Filed: May 14, 2015
(86) PCT No.: PCT/KR2015/004830

§ 371 Date: Nov. 9, 2016

(30) Foreign Application Priority Data
May 14, 2014 (KR) 10-2014-0057719

(51) Int. Cl. H01L 51/00; H01L 51/10; H01L 51/05

(52) U.S. Cl. CPC H01L 51/0049; H01L 51/0541; H01L 51/10; H01L 51/0039; H01L 51/0036; H01L 51/0558; H01L 51/0516; H01L 51/052; H01L 51/055; H01L 2251/301; H01L 2251/303

(57) ABSTRACT

The present invention relates to a carbon nanotube interlayer, a manufacturing method thereof, and a thin film transistor using the same. More specifically, the present invention provides a carbon nanotube interlayer, a manufacturing method thereof, and a thin film transistor using the same, where the carbon nanotube interlayer is a layer constituting an organic thin film transistor and comprising a conjugated polymer and a single-walled carbon nanotube between an organic semiconductor layer and a source/drain electrode. The conjugated polymer selectively wraps the single-walled carbon nanotube having semiconducting properties.

### TECHNICAL FIELD

The present invention relates to a carbon nanotube interlayer, a manufacturing method thereof, and a thin film transistor using the same, and more particularly, to a thin film transistor with enhanced performance of electronic devices.

### BACKGROUND ART

Recent years, flexible displays are receiving quite a bit of attention. The demand for flexible displays that are foldable, bendable or rollable is being driven due to the customers' desire for larger portable displays. Further, the solution process and the roll-to-roll process, if available, can make it possible to produce such flexible displays at lower cost. At this point, the requirement is the use of a substrate as flexible as plastic or stainless steel, which requires the lower processing temperature of 300° C. or below. Many researches have recently been devoted to the organic thin film transistor (OTFT) as a transistor for driver circuit that can be produced at such a low temperature. In particular, Conjugated molecules used for an active layer in the organic thin film transistor (OTFT) are generally soluble in normal organic solvents, so the printing or solution process using the conjugated molecules can be employed to make device. Further, they have the ability to change their chemical structure in the step of designing a substance to control the electrical properties.

Carbon nanotubes, on the other hand, are applicable to various fields, owing to their extraordinary optical, mechanical and electrical properties and have been actively studies for the past twenty-five years. With excellent electrical properties, carbon nanotubes are particularly expected to be applicable to different types of electronic devices. Out of the semiconducting inks that have ever been reported to be available in the solution process in the current technological level, the semiconducting single-walled carbon nanotube (sc-SWCNT) has the highest charge mobility. The charge mobility of the sc-SWCNT has the theoretical limit of 10,000 cm²/Vs and is far higher than that of crystalline silicone (Si). Like this, a strand of well-arranged sc-SWCNT has a much higher charge mobility than any silicone device and thus enables the production of the next-generation ultrahigh-speed transistors.

Hence, there has been a demand for thin film transistors with enhanced performance of electronic devices due to the increased electron mobility in the manufacture of thin film transistors using the carbon nanotubes.

### PRIOR ART DOCUMENTS

KR Laid-Open Patent Publication No. 2009-0108459

KR Laid-Open Patent Publication No. 2011-0080776

### DISCLOSURE OF INVENTION

It is an object of the present invention to provide a thin film transistor that enhances the performance of devices by reducing the trap between the electrode and the semiconductor layer.

It is another object of the present invention to provide a thin film transistor that lowers the contact resistance between the electrode and the semiconductor layer.

It is further another object of the present invention to provide a thin film transistor with high performance that shows excellences in terms of both p type and n type properties.

### TECHNICAL SOLUTION

In order to achieve the objects of the present invention, there is provided a carbon nanotube interlayer that is a layer constituting an organic thin film transistor, the carbon nanotube interlayer being a layer comprising a conjugated polymer and a single-walled carbon nanotube as disposed between an organic semiconductor layer and a source/drain electrode. The conjugated polymer selectively wraps the single-walled carbon nanotube having semiconducting properties.

The conjugated polymer of the present invention is fluorene or thiophene polymer.

The carbon nanotube interlayer of the present invention comprises 0.0001 to 0.015 mg/ml of the single-walled carbon nanotube.

The present invention also provides a method for manufacturing a carbon nanotube interlayer, which is a method for manufacturing a layer included in a thin film transistor, the method comprising: (1) mixing a conjugated polymer and a single-walled carbon nanotube in a solvent; (2) performing an ultrasonication on the mixed solution; (3) performing a centrifugation using a centrifugal separator to take a supernate; and (4) using the supernate to form a carbon nanotube interlayer between an organic semiconductor layer and a source/drain electrode. The carbon nanotube interlayer comprises a conjugated polymer and a single-walled carbon nanotube having semiconducting properties. The conjugated polymer selectively wraps the single-walled carbon nanotube having semiconducting properties.

The mixing step (1) of the present invention uses 4 to 6 mg of the conjugated polymer and 1.5 to 3.0 mg of the single-walled carbon nanotube per 1 ml of the solvent. The mixing ratio of the conjugated polymer to the single-walled carbon nanotube is 3:2 to 3:1.

The conjugated polymer of the present invention is fluorene or thiophene polymer.

The supernate of the present invention contains 0.0001 to 0.015 mg/ml of the single-walled carbon nanotube.

The present invention also provides a thin film transistor that comprises: a substrate; source/drain electrodes disposed apart from each other on the substrate; a carbon nanotube interlayer comprising a conjugated polymer and a single-walled carbon nanotube and being disposed on the whole surface of the substrate including the source/drain electrodes; an organic semiconductor layer being disposed on the whole surface of the carbon nanotube interlayer; a gate insulating layer being disposed on the whole surface of the organic semiconductor layer; and a gate electrode being disposed on the gate insulating layer. The conjugated polymer selectively wraps the single-walled carbon nanotube having semiconducting properties.

In the carbon nanotube interlayer of the present invention, the conjugated polymer is fluorene or thiophene polymer.

The carbon nanotube interlayer of the present invention contains 0.0001 to 0.015 mg/ml of the single-walled carbon nanotube.

The organic semiconductor layer of the present invention uses an N type organic semiconductor or a P type organic semiconductor. The N type organic semiconductor is selected from a substance based on acene, fully fluorinated acene, partially fluorinated acene, partially fluorinated oligothiophene, fullerene, fullerne with a substituent, fully fluorinated phthalocyanine, partially fluorinated phthalocyanine, perylene tetracarboxylic diimide, perylene tetracarboxylic dianhydride, naphthalene tetracarboxylic diimide, or naphthalene tetracarboxylic dianhydride, or a derivative thereof. The P type organic semiconductor is selected from a substance including acene, poly-thienylene vinylene, poly-3-hexylthiophene, alpha-hexathienylene, naphthalene, alpha-6-thiophene, alpha-4-thiophene, rubrene, polythiophene, polyparaphenylene vinylene, polyparaphenylene, polyfluorene, polythiophene vinylene, polythiophene-heterocyclic aromatic copolymer, or triaryl amine, or a derivative thereof.

The gate insulating layer of the present invention comprises an organic insulating layer or an inorganic insulating layer. The organic insulating layer comprises at least one selected from the group consisting of polymethylmethacrylate (PMMA), polystyrene (PS), phenol-based polymer, acryl-based polymer, imide-based polymer such as polyimide, acrylether-based polymer, amide-based polymer, fluorine-based polymer, p-xylene-based polymer, vinylalcohol-based polymer, and perylene. The inorganic insulating layer comprises at least one selected from the group consisting of silicon oxide, silicon nitride, Al₂O₃, Ta₂O₅, BST, and PZT.

The gate electrode of the present invention comprises any one selected from the group consisting of aluminum (Al), Al-alloy, molybdenium (Mo), Mo-alloy, silver nanowire, gallium indium eutectic, and PEDOT:PSS.

### ADVANTAGEOUS EFFECTS

The thin film transistor according to the present invention has the lower activation energy than the device without a carbon nanotube interlayer. This results in the reduced trap between the electrode and the semiconductor layer and hence the enhanced performance of the device.

Further, the thin film transistor according to the present invention, if having a carbon nanotube interlayer, serves to reduce the contact resistance between the electrode and the semiconductor layer. This can be one of the factors to reduce the performance of the device.

Upon a voltage of the gate being applied, the thin film transistor according to the present invention has the stronger electrical field than 2D substances to cause the rapid bending of the semiconductor bend, so the injection principle of the device changes into tunneling to accelerate the injection of holes and charges.

### BRIEF DESCRIPTION OF DRAWINGS

FIG. 1 is a diagram showing the process for manufacturing a thin film transistor according to one embodiment of the present invention.

FIG. 2 is a diagram showing the process for manufacturing a carbon nanotube interlayer according to one embodiment of the present invention.

FIG. 3 is a schematic diagram showing a wrapped carbon nanotube according to one embodiment of the present invention.

FIG. 4 shows UV-vis spectra of the carbon nanotube dispersed in the supernate.

FIG. 5 shows the transition curves in the saturation regime of N type and P type semiconductors according to Examples 1 and 2 and Comparative Example 1.

FIG. 6 shows the output curves of thin film transistors according to Examples 1 and 2 and Comparative Example 1.

FIG. 7 shows the height images of the thin films of the wrapped semiconducting carbon nanotubes in Examples 1 and 2 partly removed of the polymer by spin coating using chlorobenzene (CB).

FIG. 8 presents graphs showing the contact resistance of the transistors of Examples 1 and 2 and Comparative Example 1 using the transmission line model (TLM).

### BEST MODES FOR CARRYING OUT THE PRESENT INVENTION

Hereinafter, the present invention will be described in detail with reference to the accompanying drawings. Reference should be made to the drawings, in which the same reference numerals are used throughout the different drawings to designate the same or similar components as possible. Further, in the following description of the present invention, a detailed description of known configurations and functions incorporated herein will be omitted when it may make the subject matter of the present invention rather unclear.

The term “about or approximately” or “substantially” used in this specification are intended to have meanings close to numerical values or ranges specified with an allowable error and to prevent accurate or absolute numerical values disclosed for understanding of the present invention from being illegally or unfairly used by any unconscionable third party.

The thin film transistor of the present invention is described in association with the top gate bottom contact (TGBC) structure, but it can be applied to the bottom gate top contact (BGTC) structure as well.

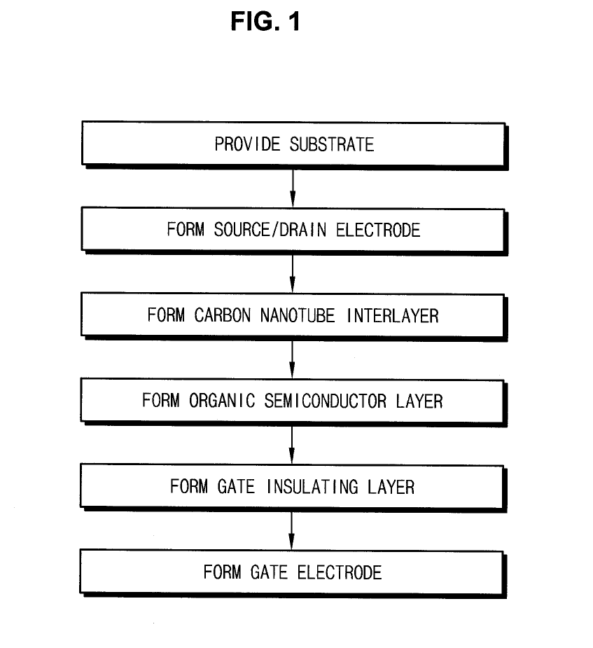

FIG. 1 is a diagram showing the process for manufacturing a thin film transistor according to one embodiment of the present invention.

A top gate type organic thin film transistor is manufactured in the steps of preparing a substrate; forming source/drain electrodes to be disposed apart from each other on the substrate; forming a carbon nanotube interlayer to cover the source/drain electrodes; forming an organic semiconductor layer on the carbon nanotube interlayer; forming a gate insulating layer on the organic semiconductor layer; and forming a gate electrode on a partial region of the gate insulating layer.

Referring to FIG. 1, a substrate is provided, and source/drain electrodes are formed on the substrate so that they are disposed apart from each other.

Examples of the substrate may include, but are not limited to, an n-type or p-type silicon wafer, a glass substrate, a plastic film selected from the group consisting of polyether sulphone, polyacrylate, polyether imide, polyimide, polyethylene terephthalate, and polyethylene naphthalate, or a glass substrate or plastic film coated with indium tin oxide.

The source/drain electrodes may be formed as a single layer selected from Au, Al, Ag, Mg, Ca, Yb, Cs-ITO, or alloy thereof; or as a multi-layer that further includes an adhesive metal layer like Ti, Cr or Ni in order to enhance the adhesion to the substrate. Moreover, graphene, carbon nanotube (CNT), PEDOT:PSS conductive polymer, silver nanowire, etc. can be used to manufacture a device having much higher elasticity than the existing metals. These substances can also be used as an ink for the printing process like ink-jet printing or spraying to make source/drain electrodes. Using the printing process to form source/drain electrodes enables it to exclude the vacuuming process, ending up reducing the production cost.

A carbon nanotube interlayer may be formed on the whole surface of the substrate including the source/drain electrodes.

The carbon nanotube interlayer may be formed with a conjugated polymer wrapping the carbon nanotubes.

The carbon nanotube interlayer may include 0.0001 to 0.015 mg/ml of single-walled carbon nanotubes contained in the conjugated polymer.

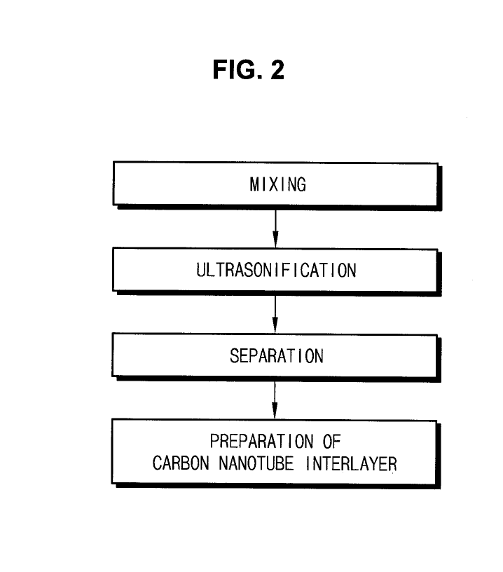

FIG. 2 is a diagram showing the process for manufacturing a carbon nanotube interlayer according to one embodiment of the present invention.

The method for manufacturing a carbon nanotube interlayer comprises: mixing a conjugated polymer and a single-walled carbon nanotube in a solvent; performing an ultrasonication on the mixed solution; performing a centrifugation using a centrifugal separator to take a supernate; and using the supernate to form a carbon nanotube interlayer between an organic semiconductor layer and a source/drain electrode.

First of all, the mixing step may involve mixing a conjugated polymer and a single-walled carbon nanotube in a solvent. Preferably, the mixing step includes using 4 to 6 mg of the conjugated polymer and 1.5 to 3.0 mg of the single-walled carbon nanotube per 1 ml of the solvent. The mixing ratio of the conjugated polymer to the single-walled carbon nanotube is preferably in the range of 3:2 to 3:1.

The defined range of the mixing ratio secures the single-walled carbon nanotube and the conjugated polymer well dispersed and mixed in the solvent.

Examples of the solvent may include chloroform, chlorobenzene, dichlorobenzene, trichlorobenzene, xylene, etc.

Preferably, the conjugated polymer of the present invention is fluorene or thiophene polymer.

The mixed solution is subjected to ultrasonification, which may be carried out at 15 to 50 Hz for about 30 to 60 minutes.

The ultrasonification on the mixed solution ends up forming a structure having the semiconducting single-walled carbon nanotube wrapped with the conjugated polymer.

The single-walled carbon nanotube displays two characteristics: semiconducting and metallic properties. The present invention selectively makes the use of the semiconducting SWNT. The substance under ultrasonification forms a structure having the single-walled carbon nanotube wrapped with the conjugated polymer. At this point, only the single-walled carbon nanotubes having the semiconducting properties can be wrapped with the conjugated polymer.

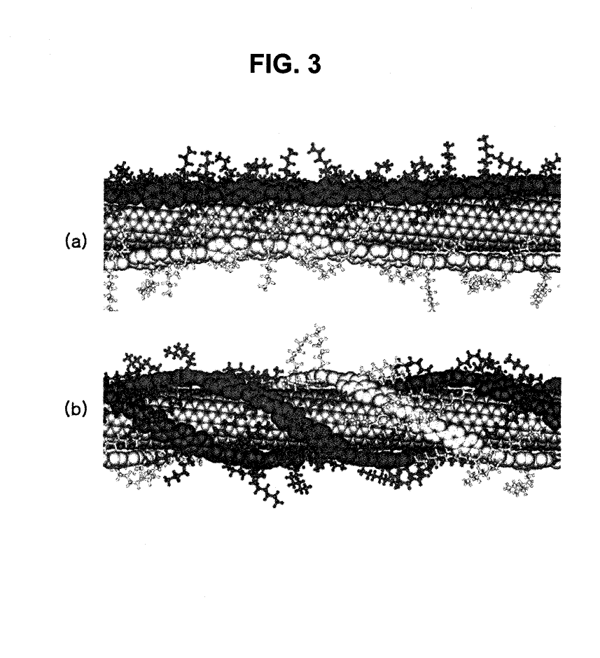

FIG. 3 is a schematic diagram showing a wrapped carbon nanotube according to one embodiment of the present invention.

The conjugated polymer surrounds the single-walled carbon nanotube in such a way that the conjugated polymer molecules are arranged in parallel as shown in FIG. 3(a) or in a twisted form as shown in FIG. 3(b).

The carbon nanotube wrapped with the conjugated polymer has a lower specific gravity than that without the conjugated polymer, so it can be isolated in the separation step.

The separation step uses a centrifugal separator to have the wrapped carbon nanotube get suspended, so that the supernate is collected to separate the wrapped carbon nanotube out.

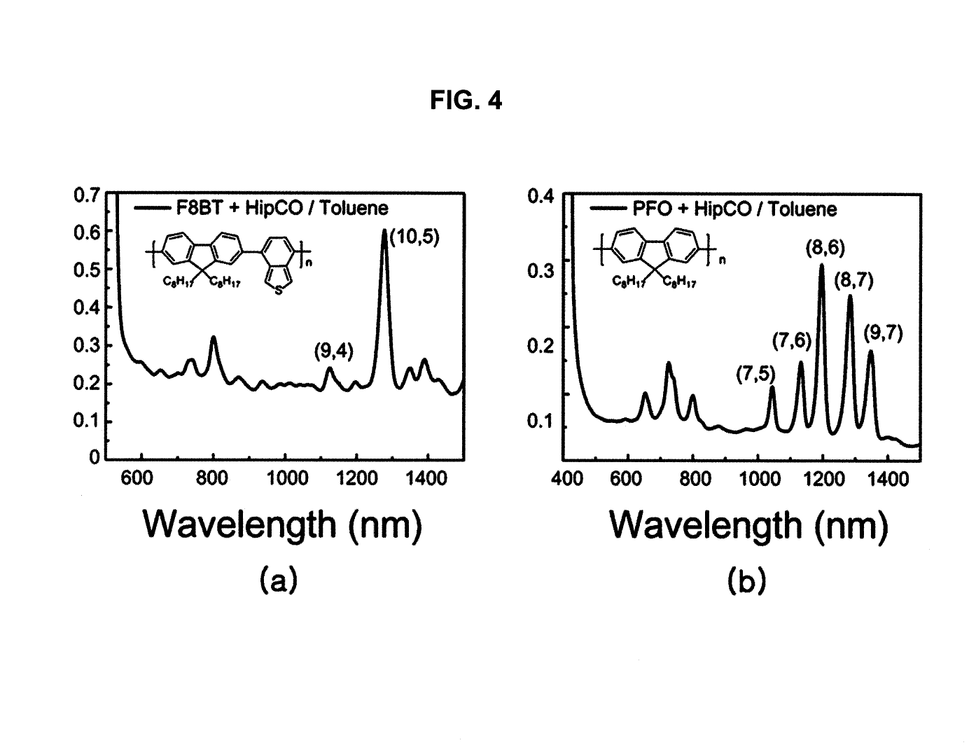

It is observed that the single-walled carbon nanotube dispersed in the supernate is the wrapped carbon nanotube having semiconducting properties. FIG. 4 shows UV-vis spectra of the carbon nanotube dispersed in the supernate.

The single-walled carbon nanotube dispersed in the supernate is proved to be a semiconducting single-walled carbon nanotube. Referring to FIG. 4, the conjugated polymer is poly(9,9-dioctylfluorene-co-benzothiadiazole) (F8BT) in (a); or PFO in (b).

In the UV-vis spectra, the semiconducting single-walled carbon nanotube absorbs light in the wavelength range of 1,000 to 1,400 nm, whereas the metallic single-walled carbon nanotube absorbs light in the range of 500 to 600 nm.

Referring to the UV-vis spectra of FIG. 4, peaks appear in the wavelength range of 1,000 to 1400 nm rather than 500 to 600 nm. This shows that the supernate contains a semiconducting single-walled carbon nanotube.

The centrifugal separation is preferably performed with a weight of 8,000 to 10,000 g. The supernate obtained by the centrifugal separation is collected and used as an interlayer between the source/drain electrodes and the semiconducting layer. That is, the supernate may be used to form a carbon nanotube interlayer that forms a layer between the organic semiconductor layer and the source/drain electrodes.

With the carbon nanotube interlayer formed between the source/drain electrodes and the organic semiconductor layer, it reduces the trap to increase the charge mobility. This results in the device having the enhanced performance.

On the whole surface of the carbon nanotube interlayer may be formed an organic semiconductor layer.

The organic semiconductor layer may use an N type organic semiconductor or a P type organic semiconductor. Preferably, the N type organic semiconductor includes any one selected from the substances based on acene, fully fluorinated acene, partially fluorinated acene, partially fluorinated oligothiophene, fullerene, fullerne with a substituent, fully fluorinated phthalocyanine, partially fluorinated phthalocyanine, perylene tetracarboxylic diimide, perylene tetracarboxylic dianhydride, naphthalene tetracarboxylic diimide, or naphthalene tetracarboxylic dianhydride. In this regard, the acene-based substance may be selected from anthracene, tetracene, pentacene, perylene, or coronene.

Further, the P type organic semiconductor may be selected from a substance including acene, poly-thienylene vinylene, poly-3-hexylthiophene, alpha-hexathienylene, naphthalene, alpha-6-thiophene, alpha-4-thiophene, rubrene, polythiophene, polyparaphenylene vinylene, polyparaphenylene, polyfluorene, polythiophene vinylene, polythiophene-heterocyclic aromatic copolymer, or triaryl amine, or a derivative thereof. In this regard, the acene-based substance is any one of pentacene, perylene, tetracene, or anthracene.

On the whole surface of the semiconductor layer may be formed a gate insulating layer.

The gate insulating layer may comprise a single layer or a multi-layer of an organic or inorganic insulating layer; or an organic-inorganic hybrid layer. The organic insulating layer uses at least one selected from the group consisting of polymethylmethacrylate (PMMA), polystyrene (PS), phenol-based polymer, acryl-based polymer, imide-based polymer such as polyimide, acrylether-based polymer, amide-based polymer, fluorine-based polymer, p-xylene-based polymer, vinylalcohol-based polymer, and perylene. The inorganic insulating layer uses at least one selected from the group consisting of silicon oxide, silicon nitride, Al₂O₃, Ta₂O₅, BST, and PZT.

On a part of the region of the gate insulating layer may be formed a gate electrode. The gate electrode may comprise any one selected from the group consisting of aluminum (Al), Al-alloy, molybdenium (Mo), Mo-alloy, silver nanowire, gallium indium eutectic, and PEDOT:PSS. The gate electrode may be prepared through the printing process, such as ink-jet printing or spraying, using the above-mentioned substances as ink. Using the printing process to form the gate electrode can exclude the vacuuming process and thus reduce the production cost.

In this manner, the thin film transistor according to one embodiment of the present invention is completed.

### MODES FOR CARRYING OUT THE INVENTION

Hereinafter, a detailed description will be given as to one embodiment of the present invention.

### EXAMPLE 1

### Preparation of Carbon Nanotube Interlayer

Chloroform is prepared as a solvent. And, a single-walled carbon nanotube and poly(9,9-dioctylfluorene-co-benzothiadiazole) (F8BT) used as a conjugated polymer are also provided.

4 mg of F8BT and 2 mg of a single-walled carbon nanotube are mixed together in 1 ml of chloroform, in the mixing step. The mixed solution is then subjected to ultrasonification; that is, it is put into an ultrasonification bath at 20 Hz for 30 minutes and then a tip sonicator for 15 minutes, in the ultrasonification step.

Upon completion of the ultrasonification process, the resulting substance is subjected to centrifugal separation using a centrifugal separator. At this point, the centrifugal separation is carried out for 5 minutes with a centrifugal separator using a weight of 9,000 g. The supernate thus obtained is collected and used in the preparation of a carbon nanotube interlayer.

### Preparation of Thin Film Transistor

The manufacture of a thin film transistor involves the steps of forming source/drain electrodes to be disposed apart from each other on the substrate; forming a carbon nanotube interlayer to cover the source/drain electrodes; forming an organic semiconductor layer on the carbon nanotube interlayer; forming a gate insulating layer on the organic semiconductor layer; and forming a gate electrode on a partial region of the gate insulating layer.

In this regard, the substrate is a glass substrate, and the source/drain electrodes are formed on the substrate through the printing process. On the source/drain electrodes is disposed the carbon nanotube interlayer that is prepared according to the “Preparation of Carbon Nanotube Interlayer”. The organic semiconductor layer is prepared using PTVPh1-Eh.

The gate insulating layer is formed from PMMA, and the gate electrode is formed from aluminum (Al) to complete a thin film transistor.

### EXAMPLE 2

The procedures are performed in the same as described in Example 1, excepting that the conjugated polymer used in the “Preparation of Carbon Nanotube Interlayer” is poly[9,9-dioctylfluorenyl-2,7-diyl] (PFO).

### COMPARATIVE EXAMPLE 1

The procedures are performed in the same as described in Example 1, excepting that a thin film transistor is prepared without forming a carbon nanotube interlayer. That is, the thin film transistor according to Comparative Example 1 comprises a substrate, source/drain electrodes, an organic semiconductor layer, a gate insulating layer, and a gate electrode.

A performance comparison of the thin film transistors according to Examples 1 and 2 and Comparative Example 1 is given as follows.

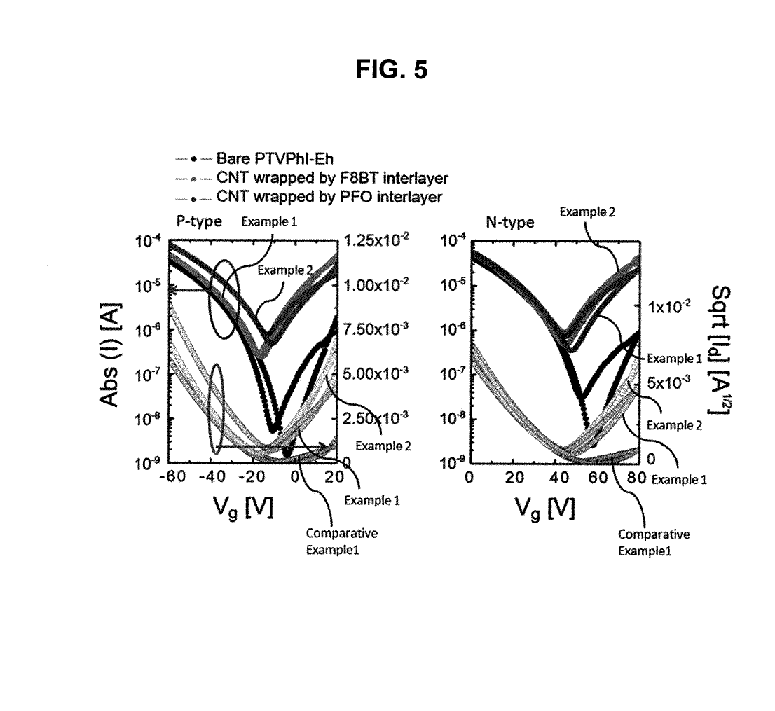

FIG. 5 shows the transition curves in the saturation regime of N type and P type semiconductors according to Examples 1 and 2 and Comparative Example 1.

FIG. 5 presents graphs showing the performance of the transistors. As shown in the P-type graphs, the transistor of Comparative Example 1 destitute of an interlayer has the lowest current. On the contrary, the transistors of Examples 1 and 2 with an interlayer display a rise of the current. This can be a direct factor to increase the charge mobility of the transistor. Likewise in the N-type graphs, the transistors of Examples 1 and 2 with an interlayer display the current increasing about 200 times and have the hysteresis disappear, while the hysteresis is shown in the graph of Comparative Example 1 devoid of an interlayer. It is general that the N-type properties decrease with an increase in the P-type properties and vice versa when there is another layer inserted between the source/drain electrode and the semiconductor layer in order to enhance the performance of the transistor. Contrarily, the n-type and p-type properties are both increased in the present invention. This shows an advantage of the present invention when the transistor is more advanced into circuitry. That is, there is no need for inserting different interlayers necessary to the N-type or P-type properties alone, so just a single substance can be used without patterning.

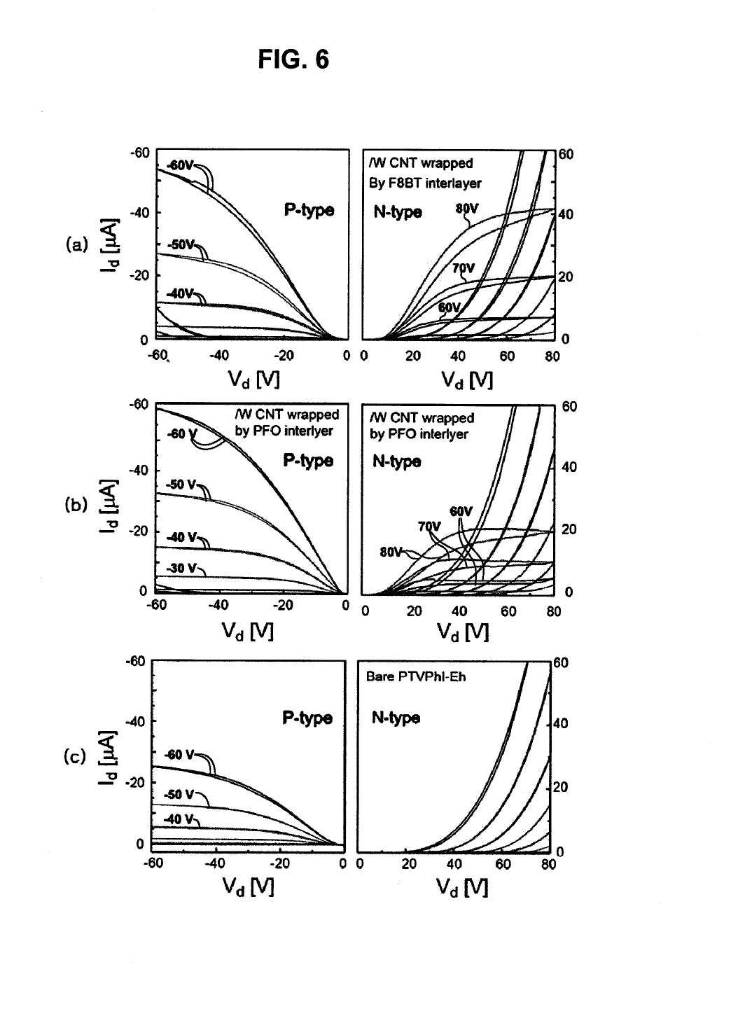

FIG. 6 shows the output curves of thin film transistors according to Examples 1 and 2 and Comparative Example 1.

The P-type and N-type output properties of the transistors of Example 1 and 2 and Comparative Example 1 are shown FIGS. 6(a), 6(b) and 6(c), respectively. As shown in the case of Comparative Example 1, which is destitute of a carbon nanotube interlayer, P-type properties appear better than N-type properties. But, as shown in the case of Example 1 or 2, which has a carbon nanotube interlayer, P-type and N-type properties are both excellent.

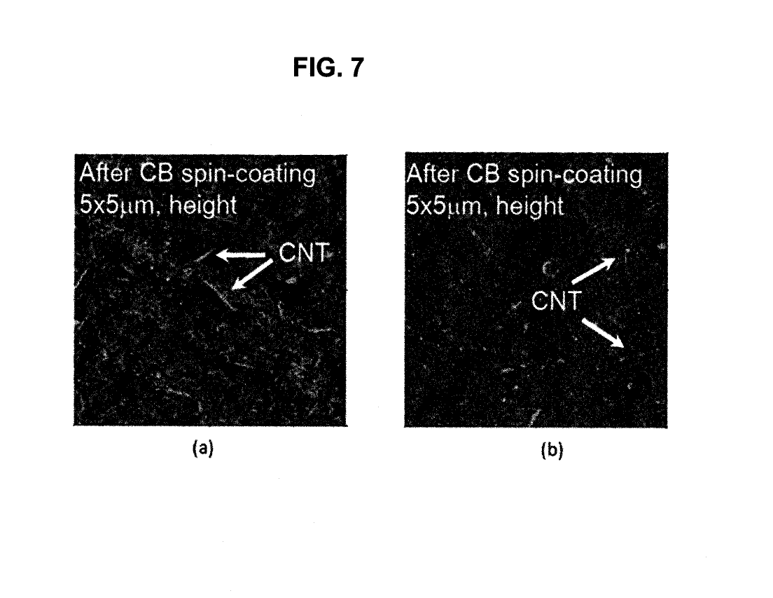

FIG. 7 shows the height image of the thin films of the wrapped semiconducting carbon nanotubes in Examples 1 and 2 partly removed of the polymer by spin coating using chlorobenzene (CB).

Referring to FIG. 7, the single-walled carbon nanotubes are dispersed in the thin film.

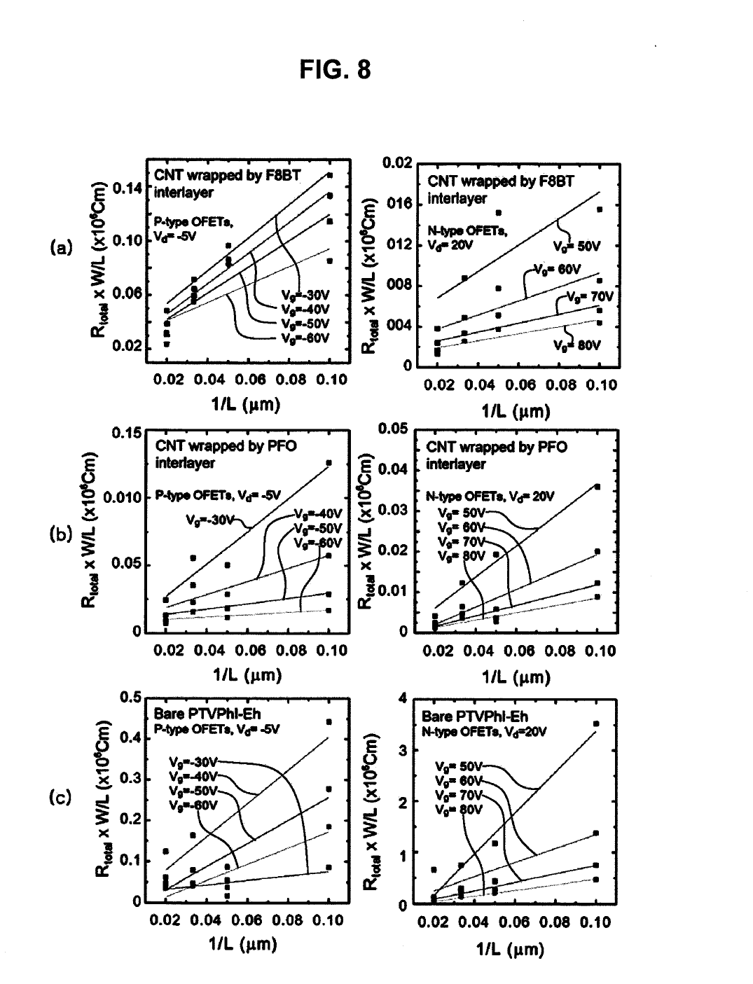

FIG. 8 presents graphs showing the contact resistance of the transistors of Examples 1 and 2 and Comparative Example 1 using the transmission line model (TLM).

The contact resistances of the transistors of Examples 1 and 2 and Comparative Example 1 are shown in FIGS. 8(a), 8(b) and 8(c), respectively. In each graph, the lower slope means the lower contact resistance. The slope of the graph for Example 1 or 2 is lower than that of the graph for Comparative Example 1. This implies that the transistor of Example 1 or 2 has the lower contact resistance than the transistor of Comparative Example 1. In other words, the reason that the thin film transistor of the present invention (Example 1 or 2) has the enhanced performance is the insertion of the carbon nanotube interlayer that reduces the contact resistance on both hole and charge sides.

The foregoing description of the invention has been presented for purposes of illustration and description and is not intended to be exhaustive or to limit the invention to the precise form disclosed, and obviously many modifications and variations are possible in light of the above teaching.

What is claimed is:

1. A carbon nanotube interlayer being a layer constituting an organic thin film transistor,
the carbon nanotube interlayer being a layer comprising a conjugated polymer and a single-walled carbon nanotube between an organic semiconductor layer and a source/drain electrode,
wherein the conjugated polymer selectively wraps the single-walled carbon nanotube having semiconducting properties.

2. The carbon nanotube interlayer as claimed in claim 1, wherein the conjugated polymer is fluorene or thiophene polymer.

3. The carbon nanotube interlayer as claimed in claim 1, wherein the carbon nanotube interlayer comprises 0.0001 to 0.015 mg/ml of the single-walled carbon nanotube.

4. A method for manufacturing a carbon nanotube interlayer, which is a method for manufacturing a layer included in a thin film transistor, the method comprising:
mixing a conjugated polymer and a single-walled carbon nanotube in a solvent;
performing an ultrasonication on the mixed solution;
performing a centrifugation using a centrifugal separator to take a supernate; and
using the supernate to form a carbon nanotube interlayer between an organic semiconductor layer and a source/drain electrode,
wherein the carbon nanotube interlayer comprises a conjugated polymer and a single-walled carbon nanotube having semiconducting properties,
wherein the conjugated polymer selectively wraps the single-walled carbon nanotube having semiconducting properties.

5. The method as claimed in claim 4, wherein the mixing step (1) uses 4 to 6 mg of the conjugated polymer and 1.5 to 3.0 mg of the single-walled carbon nanotube per 1 ml of the solvent,
wherein the mixing ratio of the conjugated polymer to the single-walled carbon nanotube is 3:2 to 3:1.

6. The method as claimed in claim 4, wherein the conjugated polymer is fluorene or thiophene polymer.

7. The method as claimed in claim 4, wherein the supernate contains 0.0001 to 0.015 mg/ml of the single-walled carbon nanotube.

8. A thin film transistor comprising:
a substrate;
source/drain electrodes disposed apart from each other on the substrate;
a carbon nanotube interlayer comprising a conjugated polymer and a single-walled carbon nanotube and being disposed on the whole surface of the substrate including the source/drain electrodes;
an organic semiconductor layer being disposed on the whole surface of the carbon nanotube interlayer;
a gate insulating layer being disposed on the whole surface of the organic semiconductor layer; and
a gate electrode being disposed on the gate insulating layer,
wherein the conjugated polymer selectively wraps the single-walled carbon nanotube having semiconducting properties.

9. The thin film transistor as claimed in claim 8, wherein the conjugated polymer of the carbon nanotube interlayer is fluorene or thiophene polymer.

10. The thin film transistor as claimed in claim 8, wherein the carbon nanotube interlayer contains 0.0001 to 0.015 mg/ml of the single-walled carbon nanotube.

11. The thin film transistor as claimed in claim 8, wherein the organic semiconductor layer uses an N type organic semiconductor or a P type organic semiconductor,
wherein the N type organic semiconductor is selected from a substance based on acene, fully fluorinated acene, partially fluorinated acene, partially fluorinated oligothiophene, fullerene, fullerne with a substituent, fully fluorinated phthalocyanine, partially fluorinated phthalocyanine, perylene tetracarboxylic diimide, perylene tetracarboxylic dianhydride, naphthalene tetracarboxylic diimide, or naphthalene tetracarboxylic dianhydride, or a derivative thereof,
wherein the P type organic semiconductor is selected from a substance including acene, poly-thienylene vinylene, poly-3-hexylthiophene, alpha-hexathienylene, naphthalene, alpha-6-thiophene, alpha-4-thiophene, rubrene, polythiophene, polyparaphenylene vinylene, polyparaphenylene, polyfluorene, polythiophene vinylene, polythiophene-heterocyclic aromatic copolymer, or triaryl amine, or a derivative thereof.

12. The thin film transistor as claimed in claim 8, wherein the gate insulating layer comprises an organic insulating layer or an inorganic insulating layer,
wherein the organic insulating layer comprises at least one selected from the group consisting of polymethylmethacrylate (PMMA), polystyrene (PS), phenol-based polymer, acryl-based polymer, imide-based polymer such as polyimide, acrylether-based polymer, amide-based polymer, fluorine-based polymer, p-xylene-based polymer, vinylalcohol-based polymer, and perylene,
wherein the inorganic insulating layer comprises at least one selected from the group consisting of silicon oxide, silicon nitride, Al₂O₃, Ta₂O₅, BST, and PZT.

13. The thin film transistor as claimed in claim 8, wherein the gate electrode comprises any one selected from the group consisting of aluminum (Al), Al-alloy, molybdenium (Mo), Mo-alloy, silver nanowire, gallium indium eutectic, and PEDOT:PSS.
